(19) United States
(12) Patent Application Publication
(10) Pub. No.: US 2026/0370116 A1
(43) Pub. Date: Nov. 19, 2026

(54) SUPPLY CIRCUIT, CORRESPONDING CONVERTER, DEVICE AND METHOD

(71) Applicant: STMicroelectronics International N.V., Geneva (CH)

(72) Inventors: Alberto Iorio, Aosta (IT); Maurizio Foresta, Aosta (IT)

(21) Appl. No.: 19/572,348

(22) Filed: Mar. 19, 2026

(30) Foreign Application Priority Data
Apr. 10, 2025 (IT) 102025000007938

(51) Int. Cl. H02M 1/00; H02J 7/00; H02J 7/96; H02M 1/15

(52) U.S. Cl. CPC H02M 1/0025; H02J 7/855; H02J 7/96; H02M 1/0012; H02M 1/0083; H02M 1/15; H02J 2207/20; H02J 2207/50

(57) ABSTRACT

A self-supply circuit for a switched-mode power supply converter comprises a first node configured to receive a switched voltage, a second node configured to produce a load current, and a capacitor coupled to the second node and configured to provide the load current in response to electrical charge being drawn therefrom. A switch coupled between the first node and the second node is configured, when conductive, to provide a current flow line for a charge current between the first node and the capacitor coupled to the second node so that electrical charge is charged onto the capacitor via the charge current. Control circuitry of the switch is configured to detect the voltages at the first and second nodes and to render the switch conductive during a charging time of the capacitor in response to the voltage at the first node being higher than the voltage at the second node.

### CROSS-REFERENCE TO RELATED APPLICATIONS

This application claims the priority benefit of Italian patent application number 102025000007938, filed on Apr. 10, 2025, entitled “Supply circuit, corresponding converter, device and method,” which is hereby incorporated herein by reference to the maximum extent allowable by law.

### TECHNICAL FIELD

The description relates to supply circuits and methods.

Solutions as described herein can be applied, for instance, in switching converters such as AC/DC or DC/DC converters.

Electronic power supply circuitry that incorporates a switching regulator to convert electrical power efficiently such as switched-mode power supply (SMPS) converters are exemplary of possible applications of solutions as described herein.

### BACKGROUND

Conventional electronic power supply circuitry includes an auxiliary transformer with a rectifier and an associated filter capacitor. This may give rise to fairly complex circuit architecture involving a relatively large number of components.

There is a need in the art to contribute in providing improved solutions primarily as regards the possibility of simplifying converter architecture and reducing the number of components involved in an application.

### SUMMARY

According to one or more solutions as described herein, such an object can be achieved via a circuit having the features set forth in the claims that follow.

Switching converters such as AC/DC or DC/DC converters, namely electronic power supply circuitry that incorporates a switching regulator to convert electrical power efficiently such as switched-mode power supply (SMPS) converters are exemplary of possible applications of solutions as described herein.

Solutions as described herein can also relate to a corresponding device. A device comprising an integrated circuit (IC) configured to be self-supplied via such a switching converter can be exemplary of such a device.

Solutions as described herein can also relate to a corresponding method.

The claims are an integral part of the technical teaching provided herein in respect of the embodiments.

Circuits as proposed herein can be used, for instance, in switched-mode power supply (SMPS) converters to self-generate a supply voltage for an integrated circuit (IC) with high efficiency via a switching node (usually a high voltage node) of the converter.

While suited to be advantageously used in synchronous rectifiers (SRs) for flyback converters, circuitry as proposed herein can be used in all types of SMPS converters.

Solutions as described herein facilitate simplifying converter architecture and reducing the number of components therein. For instance, a synchronous rectifier in a high-side configuration can be supplied directly via a switching node of a flyback converter (output of the secondary winding of the transformer in the converter) without relying on an external supply voltage provided via an auxiliary winding of the transformer, a rectifier and a filter capacitor coupled therewith.

A concept that underlies solutions as described herein is to charge a supply node (this may be a node of an integrated circuit where a self-supply circuit is implemented) during a rising edge occurring at the switching node with a high peak current, in order to charge an associated capacitor from a low(est) equivalent voltage, thus improving the efficiency of the self-supply circuit. The duration of such a charging current can be controlled via a regulation control loop to set to a target value the supply voltage.

Solutions as described herein facilitate implementing active diode devices intended to replace standard diode rectifiers for converters (flyback or other types of SMPS converters).

Solutions as described herein can be applied to GaN enhancement mode transistors (HEMTs) to provide a synchronous rectifier controller for a GaN transistor with an integrated self-supply circuit acting through the cathode pin with a supply capacitor either integrated in a system in package (SiP) or arranged outside and coupled through a dedicated pin.

Solutions as described herein can also be applied to standard MOSFET transistors to provide a synchronous rectifier controller for a MOSFET transistor with an integrated self-supply circuit acting through the cathode pin with a supply capacitor either integrated in a system in package (SiP) or arranged outside and coupled through a dedicated pin.

Solutions as described herein facilitate generating a supply voltage for an integrated circuit (IC) directly from the switching node of an SMPS converter. Such an arrangement can be used to replace standard diodes in an SMPS converter.

Types of converters to which solutions as described herein can be advantageously applied include:
boost converters,
forward converters,
flyback converters,
push-pull converters, and
LLC resonant converters.

Solutions as described herein facilitate achieving a reduction of occupied semiconductor area and cost savings by taking advantage of the switching node of a converter to generate with good efficiency a supply voltage of an integrated circuit.

In high-side configuration rectifiers, solutions as described herein can avoid the use of an auxiliary winding (and the associated rectifier and filter capacitor), thus giving rise to a compact solution where a power transistor and a synchronous rectifier (SR) driver can be integrated in a same package, achieving efficiency similar to the efficiency of a MOS rectifier.

Simulation results confirm that, if the charging phase is fast enough, a self-supply circuit as described herein shows a good efficiency, comparable to an external supply (a SMPS converter output) at 20V.

Reduction of area occupancy is facilitated by the absence of a supply pin to be connected to an output voltage of a SMPS converter or to a (rectified) auxiliary winding voltage of in the converter transformer, while the supply pin of the integrated circuit may be connected only to a capacitor.

Measuring the peak current of the switching node during a rising edge thereof may be indicative of the use of solutions as proposed herein.

### BRIEF DESCRIPTION OF THE DRAWINGS

One or more embodiments will now be described, by way of example only, with reference to the annexed figures, wherein:

FIG. 1 is a diagram illustrative of a basic concept that underlies solutions as described herein;

FIG. 2 shows a possible context of use of circuitry based on the diagram of FIG. 1 in a flyback converter with rectifier in a high-side configuration;

FIG. 3 is circuit diagram of a self-supply circuit according to solutions as described herein in case of a rectifier used in low-side configuration;

FIG. 4 is a timing diagram showing possible time behaviors (waveforms) of signals that may occur in a circuit as illustrated in FIG. 3;

FIG. 5 is a timing diagram showing a more realistic representation of certain signals visible in FIG. 4;

FIG. 6 is a circuit diagram of a possible practical implementation of a portion of solutions as described herein;

FIG. 7 is a timing diagram showing possible time behaviors (waveforms) of signals that may occur in a circuit as illustrated in FIG. 6;

FIG. 8 is a diagram showing a possible relationship between parameter of a circuit as illustrated in FIG. 6;

FIG. 9 is a circuit diagram of a possible practical implementation of a component (switch) suite for use in solutions as described herein; and

FIG. 10 is a timing diagram showing possible time behaviors (waveforms) of signals that may occur in operation of a component as illustrated in FIG. 9.

The figures are drawn to clearly illustrate relevant aspects of the solutions described herein and are not necessarily drawn to scale.

The edges of features drawn in the figures do not necessarily indicate the termination of the extent of the feature.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular configurations, structures, or characteristics may be combined in any adequate way in one or more embodiments.

The headings/references used herein are provided merely for convenience and hence do not define the extent of protection or the scope of the embodiments.

Unless the context indicates otherwise, like parts or elements are indicated throughout the figures annexed herein with like references/numerals and a corresponding description will not be repeated for the sake of brevity.

For the sake of simplicity and ease of explanation, a same designation may be applied throughout this description to designate:
a node or line as well as a signal occurring at that node or line;
a component (such as a capacitor, resistor or inductor or coil) as well as electrical parameters (capacitance, resistance, inductance) thereof.

Also, when it is mentioned that an element is “connected to” or “coupled to” another element, it should be understood that an element may be coupled directly to another element or that still another element may be interposed therebetween.

On the contrary, when it is possibly mentioned that an element is “connected directly to” or “coupled directly to” another element, it should be understood that still another element is not interposed therebetween.

Solutions as described herein by way of example are related to generating a supply voltage for integrated circuits for switching applications such as switched-mode power supply (SMPS) converters starting from the switching node of the converter.

Such solutions facilitate achieving a good conversion efficiency with an implementation easy enough to make such solution particularly attractive for possible use in power circuits for integrated circuits.

For instance, solutions as described herein facilitate realizing via a System-In-Package (SIP) a synchronous rectifier that is self-powered by the switching node.

Such an arrangement can be used, for instance, in converters such as flyback switching converters by replacing one or more diodes therein with a pin-to-pin compatible solution, with a notable efficiency gain and without having to modify by way of necessity circuit boards already implemented for that purpose.

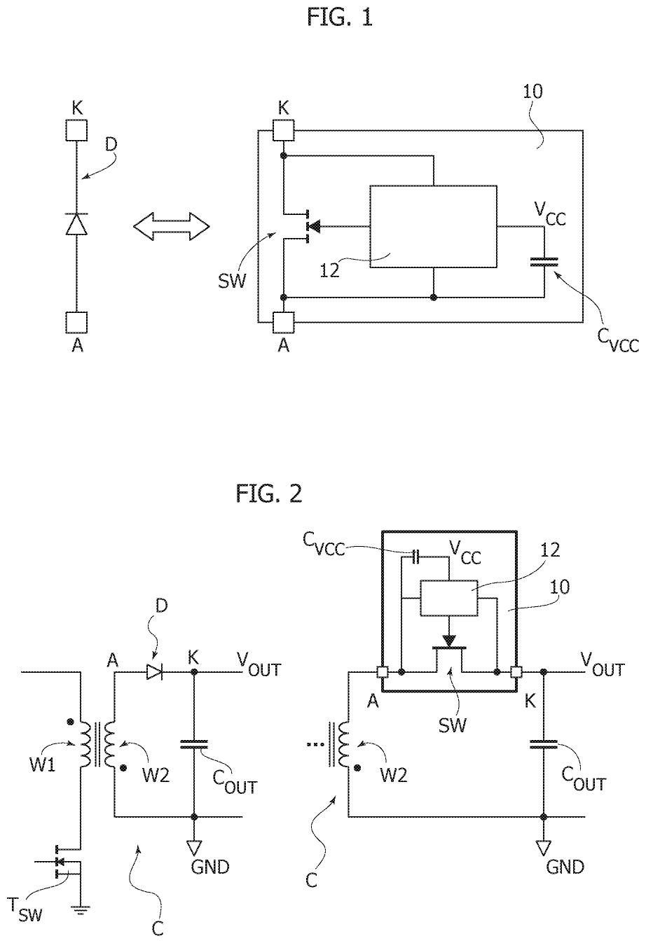

FIG. 1 is a diagram illustrative of a basic concept that underlies solutions as described herein used to implement a “self-supply” arrangement for a (high-efficiency) synchronous rectifier.

More in detail:
the left-hand side of FIG. 1 shows a diode D having an anode terminal or node A and a cathode terminal or node K; and
the right-hand side of FIG. 1 shows a circuit 10 including a switch SW (a semiconductor switch such as a GaN enhancement mode transistor, HEMT) having a current flow path (source-drain, in the case of a GaN transistor) between the nodes A and K as well as control terminal (gate, in the case of a GaN transistor) driven by a circuit implemented as a System In Package (SIP) built around a transistor such as a GaN transistor to improve efficiency and configured to act as a synchronous rectifier (SR) and a self-supply circuit 12, that is as a driver for synchronous rectification for the transistor in co-operation with a power supply capacitance C_{VCC}: as discussed in the following a charging phase can occur in the absence of a current flow between the nodes A and K and a switching node (here K) “moves” and facilitates charging the capacitance C_{VCC} via a self-supply circuit.

The capacitance C_{VCC} (having applied a voltage V_{CC}) is illustrated here as included in the circuit 10, but could also be an external component (by creating a 3-pin circuit, for instance).

The right-hand side of FIG. 2 exemplifies how such a self-supply circuit 12 with synchronous rectification (SR) driver and a control switch SW (a GaN or MOSFET transistor, for instance) can be used to replace a diode D (left-hand side of FIG. 2).

A high-side configuration is illustrated by way of non-limiting example in so far as this configuration exhibits better performance in terms of electromagnetic interference (EMI) in comparison with a low-side configuration in a flyback converter to control charging of an output capacitor C_{OUT} coupled between the node K (at a voltage VOUT) and a ground GND with the node A coupled to the secondary winding W2 of a transformer whose primary winding W1 (visible for simplicity only on the left-hand side of FIG. 2) is cascaded with a switch T_{SW} (this may be a semiconductor switch such as field effect transistor, FET).

It is otherwise again noted that referring herein to a flyback converter is merely by way of example is so far as solutions as described herein can be advantageously applied to a variety of switching converter types including, in addition to flyback converters, boost converters, forward converters, push-pull converters, and LLC resonant converters, just to name a few.

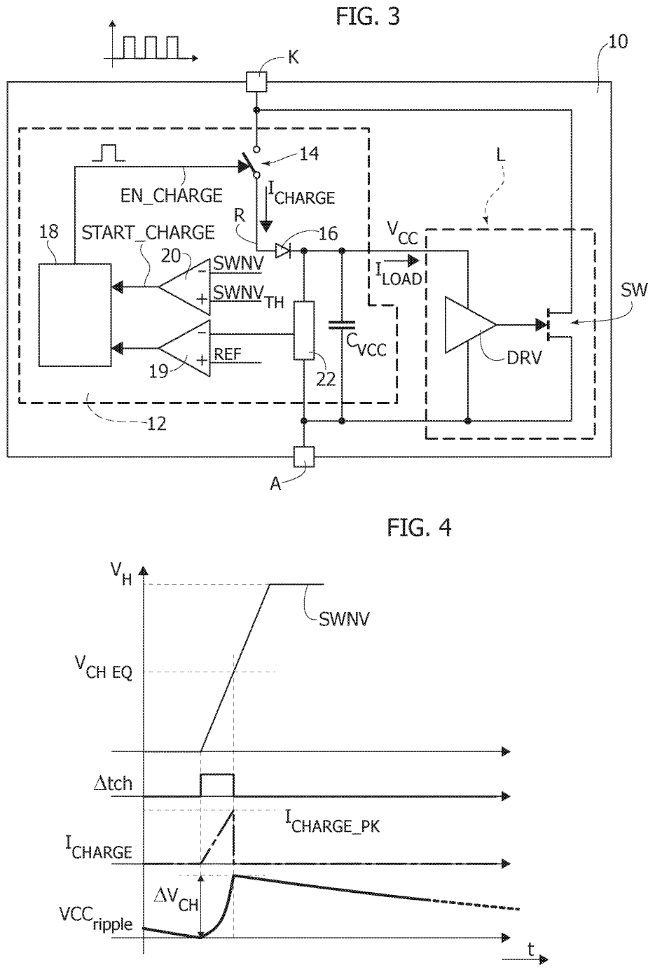

FIG. 3 is a more detailed block diagram of the self-supply circuit 12 where parts or elements like parts or elements already introduced in the foregoing are indicated with like reference symbols.

A concept underlying solutions as described herein is to realize a circuit that is able to charge the capacitor C_{VCC} on the power supply node (at the voltage V_{CC}) of the integrated circuit where the self-supply circuit 12 is used during a rising edge of the switching node (node K in the example shown) of the converter with a (high) charging current I_{CHARGE} drawn from that node K via a switch 14: this can again be an electronic switch such as a transistor (a FET, for instance) coupled between the node K and a node R to which the capacitor C_{VCC} is in turn coupled via a diode 16.

As shown by way of example, the diode 16 has its anode coupled to the switch 14 at the node R and its cathode coupled to the capacitor C_{VCC} which is arranged between the diode 16 and the node A.

In a circuit as illustrated in FIG. 3 the capacitor C_{VCC} is charged in a (fast) time Δtch via a pulse that closes (and thus renders conductive) the switch 14, so that the charge energy can be provided via an equivalent voltage that is as low as possible, which results in an improved conversion efficiency.

The “on” pulse for the switch 14 sets the duration of the charging time window Δtch (this is designed to be as short as possible to obtain high efficiency) and is produced as an EN_CHARGE signal via a charging window generator 18 that is activated during the rising edge of a signal from a switching node comparator 20 and is used to set the charge voltage V_{CC} for the capacitor C_{VCC} to a target value (for instance 20V) with a dedicated control loop.

That dedicated control loop includes a comparator 19 configured to compare with a (possibly adjustable) threshold REF a sensing signal provided by a sensor 22 that is coupled to the cathode of the diode 16 and is thus sensitive to the charge voltage of the capacitor C_{VCC} and thus to the voltage V_{CC}.

In that way, a value V_{CC} as desired can be set for the charge voltage of the capacitor C_{VCC} from which a load current I_{LOAD} can be derived to supply a load L. This load is illustrated in dashed lines in FIG. 3 as a GaN synchronous rectification (SR) switch SW driven via an associated SR driver DRV.

It is noted that the load L may not be a part of the embodiments and can be notionally any type of load (any associated self-supplied integrated circuit, for instance).

FIG. 4 is a timing diagram showing—against a common abscissa time scale t —possible time behaviors (waveforms) of signals that may occur in a circuit as illustrated in FIG. 3.

More specifically, in FIG. 4 possible time behaviors are shown of the following signals (from top to bottom):
a voltage SWNV at the switching node K, ramping up from 0 to V_{H};
the pulse signal Δtch (EN_CHARGE), which, when “high”, causes the switch 14 to be conductive and is returned to “low” in response to the voltage SWNV at the node K reaching an intermediate value V_{CH_EQ};
the charge current I_{CHARGE} forwarded towards the capacitor C_{VCC} via the diode 16, ramping up to a peak value I_{CHARGE_PK} in response to the switch 14 being closed (rendered conductive); and
the ripple, designated VCCᵣᵢₚₚₗₑ, of the voltage across the capacitor C_{VCC}.

In steady-state conditions, once the voltage V_{CC} has reached its desired value, the load current I_{LOAD} applied to the load (the integrated circuit to be powered for instance), causes the capacitance C_{VCC} to be discharged by a voltage equal to ΔV_{DISCH} in a switching cycle.

The capacitance C_{VCC} is charged in a switching cycle, via the current I_{CHARGE}, by a quantity equal to ΔV_{CH}. The ripple on the voltage V_{CC}, given by ΔV_{DISCH}, depends on parameters such as I_{LOAD}, C_{VCC} and on the period of the switching signal T_{SW} NODE at the switching node (here the node K) through the following formula:

ΔV_{DISCH}=I_{LOAD}/C_{VCC}·T_{SW NODE}

The discharge equal to ΔV_{DISCH}, corresponds to a reduction of charge ΔQ_{DISCH} equal to:

C_{VCC}·ΔV_{DISCH}=I_{LOAD}·T_{SW NODE}.

A circuit as illustrated in FIG. 3 is designed to facilitated re-charging (ΔV_{CH}) via the self-supply circuit the charge (ΔV_{DISCH}) lost in a switching cycle.

In a switching cycle then:

ΔV_{CH}=ΔV_{DISCH}

which can be re-written in terms of charge variation:

ΔQ_{CH}=ΔQ_{DISCH}

ΔQ_{CH}=I_{CHARGE}·Δt_{CH}=ΔQ_{DISCH}

From that relationship one can obtain the minimum value of the charging time Δtch that facilitates maintaining the voltage at the capacitor C_{VCC} constant as a function of the current I_{LOAD} absorbed by the load:

Δt_{CH}=ΔQ_{DISCH}/I_{CHARGE}

Efficiency of the circuit that generates the voltage V_{CC}, can be optimized by deriving the charge ΔQ_{CH} from the minimum equivalent voltage of the switching node V_{CH_EQ}.

This voltage value can be reduced (minimized) by:
reducing the charging time Δtch,
p increasing the peak charging current I_{CHARGE_PK}.

The switch 14 (arranged in series with the charging path of the capacitor C_{VCC} via the diode 16) is designed in order to facilitate a shortest turn-on time compatible with having a lowest series resistance R_{ONSW} of the switch when conductive.

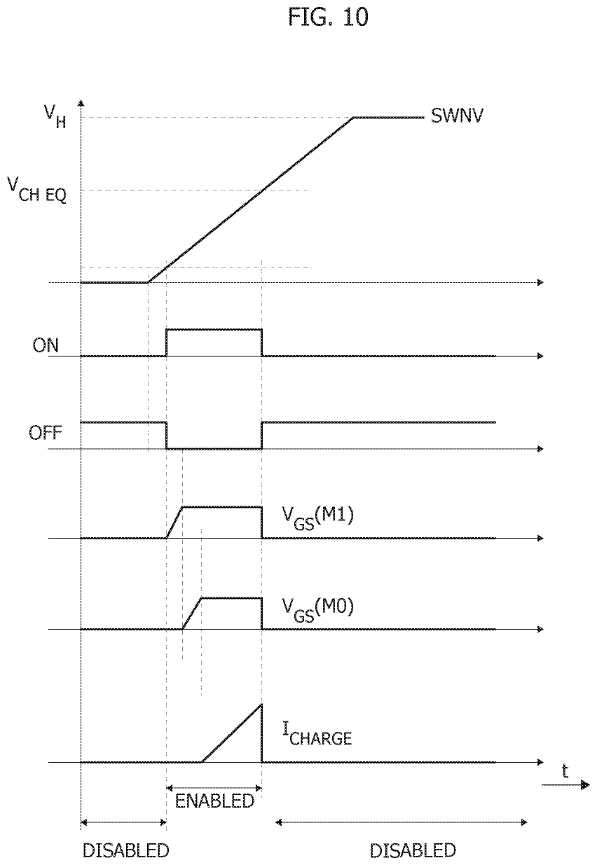

Reducing the resistance R_{ONSW} involves increasing the dimensions of the component acting as the switch, which in turn (due to increased parasitic capacitance) militates against having a reduced turn-on time: solutions as described herein may however advantageously resort to a “fast” turn-on switch (as discussed in the following in connection with FIG. 9 and FIG. 10) that facilitates satisfactory performance even if those two characteristics are difficult to achieve jointly.

Solutions as described also benefit from the peak value I_{CHARGE_PK} of the charge current being selected by taking into account the specifications of the converter where the self-supply circuit is implemented.

For instance, if it is desired to reduce the disturbances generated on the primary circuit of the converter by a peak current that is too high, that peak value can be scaled down; this facilitates complying with the noise specifications by otherwise accepting a lower efficiency.

The relationships introduced in the foregoing can be verified by simulation comparing two cases:
the charge Q_{CH} taken during the rising edge of the switching node (here, node K); and
the charge Q_{CH} taken when the switching node is at its maximum (peak) value (see V_{H} in the upper curve in FIG. 4).

The dissipated power P_{DISS} can be evaluated as:

P_{DISS}=V_{SW_NODE}·I_{CHARGE}

The results of simulation confirm that if the charging phase is fast enough, a self-supply circuit as described herein shows a good efficiency, comparable to the situation of a power supply was taken from a 20V voltage generator (compared with, say, 100V of the switching node K, which amounts to a 5-fold gain factor).

Of course, the quantitative values reported here are merely exemplary and non-limiting.

Simulation results are further confirmed by prototypes-even though these were not optimized to achieve a highest level of efficiency-with the capability of operating in both quasi-resonant (QR) and active clamp flyback (ACF) topologies. Even in the presence of a voltage V_{CC} of 4V (against 5V, which may cause an increase in the “on” resistance R_{DSON} of a GaN transistor used as a switch) solutions as propose herein offer an efficiency comparable to the efficiency of conventional MOSFET-based synchronous rectification (with a resistance R_{DSON} similar to that of a GaN transistor), with a marked improvement over a conventional diode solution.

A circuit layout as illustrated in FIG. 3 facilitates implementing switched-mode power supply (SMPS) converters and includes a control loop to regulate the supply voltage (self-generated starting from a switching signal) for a generic integrated circuit.

Such a solution can be advantageously used in those applications/contexts where providing a regulated supply voltage is hardly feasible without adding further components and complexity or where, even if present, such a regulated supply voltage cannot be used advantageously for efficiency reasons (because it is too high, for instance).

Solutions as proposed herein may involve a low-impedance switching node, suited to convey power to be transferred to the circuit output, from which current—and therefore power—are drawn (only) during a first portion of the rising edge of a signal (therefore at a lower voltage than the peak value) to generate a supply voltage for a load (an integrated circuit, for instance: the lower the voltage of the switching node when the current is drawn to generate the supply voltage, the lower the power drawn from the converter.

Solutions as proposed herein may be configured to reduce (minimize) the power drawn from the application to generate a supply voltage for a load (an IC, for instance) and to likewise reduce (minimize) the ripple due to the charge/discharge flow involved in the power supply action.

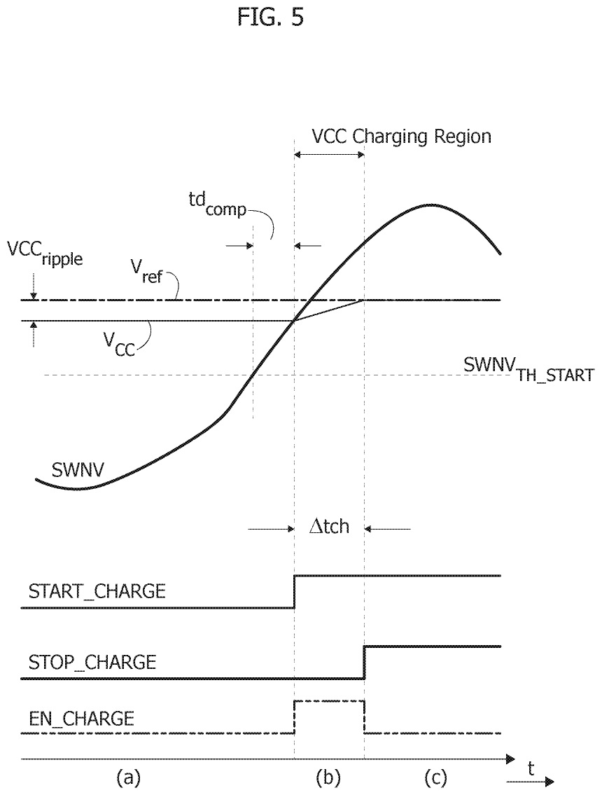

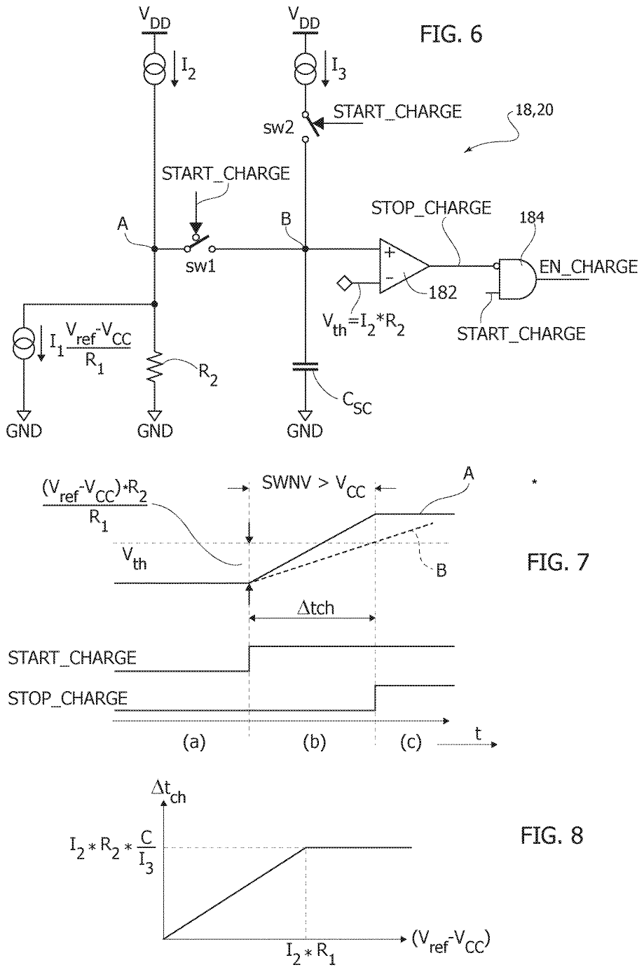

FIG. 5 is a timing diagram showing—again against a common abscissa time scale t—possible time behaviors (waveforms) of signals that may occur in a circuit as illustrated in FIG. 3 (and in FIG. 6 as well).

More specifically, in FIG. 5 possible time behaviors are shown of the following signals (from top to bottom):
the switching node voltage, SWNV namely the voltage of the low impedance switching node from which the current is drawn to charge the capacitor C_{VCC} at a voltage V_{CC} so that a load current to be supplied to an associated load (an integrated circuit, for instance) can be derived therefrom: in FIG. 5 a more realistic representation of the voltage SWNV is provided in comparison with FIG. 4;
a target value Vref (illustrated in chain line) set for the generated power supply at the voltage V_{CC};
the generated supply voltage V_{CC}, which is shown to reach the target value V_{ref} during a VCC Charging Region that starts with a delay td_{comp} (introduced by the comparator 20 visible in FIG. 3) with respect to the time instant at which the switching node voltage, SWNV reaches a “start” threshold SWNV_{TH};
a START_CHARGE signal that marks, with the delay td_{comp}, the start of the VCC Charging Region that has a duration Δtch;
a STOP_CHARGE signal that marks the end of the VCC Charging Region after the duration Δtch; and
a signal EN_CHARGE that is “high” during the VCC Charging Region and is “low” otherwise.

To summarize, the circuit diagram of FIG. 3 and the timing diagrams of FIGS. 4 and 5 are exemplary of circuit 10 comprising a first node K configured to have a switched voltage SWNV applied thereto and a second node V_{CC} configured to produce a load current I_{LOAD} to be supplied to a load L.

A circuit as illustrated in FIG. 3 comprises: the capacitor C_{VCC} coupled to the second node V_{CC} wherein the capacitor C_{VCC} is configured to provide the load current I_{LOAD} in response to electrical charge being drawn therefrom,
the switch 14 coupled between the first node K and the anode (node R) of the internal diode 16 whose cathode is connected to the node V_{CC}; when conductive, the switch 14 provides a current flow line for the charge current I_{CHARGE} between the first node K and the capacitor C_{VCC} (through the internal diode 16) that is coupled to the node V_{CC}; electrical charge is thus charged onto the capacitor C_{VCC} via the charge current I_{CHARGE}, and
control circuitry (exemplified by the blocks 18, 19 and 20 in FIG. 3) for the switch 14; such control circuitry 18, 19 and 20 is configured to detect the voltage SWNV at the first node K and the voltage at the second node V_{CC} and to render the switch 14 conductive during a charging time (having a duration Δtch between the rising edges of the signals START_CHARGE and STOP_CHARGE in FIG. 5) of the capacitor C_{VCC} in response to the voltage SWNV at the first node K being higher than the voltage at the second node V_{CC}.

An idea underlying advantageous implementations of solutions as proposed herein is to control the V_{CC} charging time window (that is, the time Δtch) with the aim or reducing (minimizing) its amplitude or duration.

As visible in FIG. 5, during the Δtch time, the voltage SWNV is higher than the value V_{CC}: it is possible to charge the storage capacity C_{VCC} of the power supply at the voltage V_{CC} by enabling (rendering conductive) the switch 14 arranged between the node K at the voltage SWNV and the node R, which determines the voltage V_{CC}. In response to being conductive, the switch 14 facilitates current flow between the node K at the voltage SWNV and the node R for the entire duration of the time interval Δtch, which results in an increase of the value of the voltage V_{CC}.

It is noted that as the recharge time of the capacitor C_{VCC} (voltage V_{CC}) increases, that is, becomes longer, the value reached by the voltage SWNV during current draw becomes higher, with a consequent increase in the absorbed power (I_{CHARGE}*SWNV).

The signal EN_CHARGE (lowermost curve in FIG. 5) defines the duration Δtch of the VCC Charging Region and enables the switch 14 to facilitate recharging of the output voltage V_{CC}.

As noted, FIG. 5 is intended to provide a more realistic representation of signal that may occur in a circuit as generally illustrated in FIG. 3.

For instance, the signal EN_CHARGE in FIG. 5 goes “high” at the transition of the START_CHARGE signal obtained as the output of a comparator that can be regarded, essentially, as a comparator that compares the voltage SWNV with the voltage V_{CC}. A possible implementation of such a comparator is discussed in the following.

Ideally, a transition in the signal START_CHARGE may be expected to occur exactly when the signal SWNV crosses the value of the voltage V_{CC}.

However, any comparator introduces a propagation delay (at least 20ns may be an exemplary and non-limiting value) that may not be negligible with respect to the rise time of the signal SWNV signal and therefore of the time interval Δtch.

A voltage threshold SWNV_{TH} (lower than the target value for V_{CC} or somehow related to the value of V_{CC}) can be used as an input to the comparator in such a way as to anticipate the intersection between the voltage SWNV and the voltage V_{CC} by a time adequate to compensate for the delay (see td_{comp} in FIG. 5) introduced by the comparator.

In that way, the upward transition of the signal START_CHARGE will occur very close to (notionally exactly at) the intersection of the voltages SWNV and V_{CC}.

The signal EN_CHARGE can return to the zero level (terminating the charging time window Δtch) in response to an upward transition of the signal STOP_CHARGE.

Solutions as described herein can take advantage of the STOP_CHARGE signal being adequately produced by programming/setting the time interval Δtch as a function of the difference between the target value Vref and the actual value of the voltage V_{CC} (instantaneous or, possibly, filtered to remove undesired noise components) sampled at the (low-to-high, for instance) transition of the START_CHARGE signal.

Under steady state conditions, the distance between the voltages V_{ref} (the target value for the voltage V_{CC}) and V_{CC}, namely V_{ref}−V_{CC}, is due only to the current consumption of the load (integrated circuit, for instance) supplied via the generated power supply voltage V_{CC}.

A possible, advantageous control law for the voltage V_{CC} is:

Δtch =f(V_{ref}−V_{CC}),

where f(x) is a monotonically increasing function.

The equation above shows that an increasing error on the voltage V_{CC} with respect to V_{ref} (distance V_{ref}−V_{CC}) will result in an increase in the time duration Δtch of the consequent V_{CC} charging time.

A corresponding control circuit may take into account a charge balance equation at the end of the charging window of duration Δtch:

(I_{CHARGE}/C_{VCC})*Δtch=α*(V_{ref}−V_{CC})+Q_{cons}/C_{VCC}

where:

α is a coefficient (ideally equal to 1) that defines the gain of the regulation loop of the voltage V_{CC} and affects the transient behavior at converter power-on;

I_{CHARGE} is the charging current generated by the Self supply circuit taken from the SWNV node (node K in FIG. 3);

Q_{Cons} is the charge consumption at each cycle of the load (IC, for instance) powered by via the voltage V_{CC}.

In a steady-state condition, where (V_{ref}−V_{CC}) is nearly 0V, the voltage ripple on the supply node at the voltage V_{CC} is equal to VCCᵣᵢₚₚₗₑ=Q_{cons}/C_{VCC}.

Adequately sizing the self-supply circuit and defining the current I_{CHARGE}, based on the expected consumption of the associated load (IC powered at the voltage V_{CC}, for instance) facilitates imposing a desired voltage ripple level on the generated power supply.

A residual error on the voltage V_{CC} may remain in steady-state conditions at the end of the charge window due to the transition of the signal START_CHARGE failing to occur exactly when the signal SWNV crosses the value V_{CC}.

Again to summarize, the control circuitry of the switch 14 is configured to:
receive a target value V_{ref} for the voltage at the second node V_{CC}, and
control the charging time Δtch as a function of the difference between the target value V_{ref} and an actual value of the voltage at the second node V_{CC}.

Considering FIG. 5, charging of the storage capacity C_{VCC} (FIG. 3) to “self-generate” the power supply voltage V_{CC} can be divided into three phases labeled (a), (b), and (c) at the bottom of FIG. 5.

During phase (a), the voltage SWNV is lower than the voltage V_{CC}: this is typically the power transfer phase for operation of an SMPS converter. In that phase, the value V_{CC} is determined (only) by the absorption by the load (integrated circuit, for instance) powered thereby The signals for self-supply management are at logic zero.

Phase (b) starts as soon as the voltage SWNV at the switching node exceeds the value V_{CC} (this is typically at the end of the power transfer phase of the converter). During that time, the self-supply circuit is enabled via the signal EN_CHARGE: the current I_{CHARGE} starts to flow from the switching node SWNV to charge the storage capacity C_{VCC} of the power supply. This operation phase is maintained until the control circuit generates the STOP_CHARGE signal. During the charging phase, the voltage V_{CC} increases in value.

In the phase (c), once charged, the voltage at the switching node, SWNV will continue to increase while consumption of the load (integrated circuit) connected thereto will be drawn from the voltage V_{CC}.

The load—see L in FIG. 3—can be simply an (integrated circuit) synchronous rectifier driver or any other auxiliary circuit useful for operation of an entire SMPS converter.

The converter will then return to phase (a) in compliance with expected operation: the signal SWNV will return below the value V_{CC} while an associated control circuitry 180 may reset the signals START_CHARGE and STOP_CHARGE to logical zero.

A possible circuit implementation of such control circuitry 180 (numbering akin to the numbering 18 in FIG. 3 is deliberately adopted in view of the notional similarity of function, even though the practical implementation is different) is illustrated in FIG. 6.

It is noted that FIG. 3 is a simplified block diagram of a possible implementation of a self-supply circuit that can be used to power a SIP containing a synchronous rectifier (SR) driver and an electronic switch such as GaN transistor.

The block diagram of FIG. 3 is primarily intended to show the basic concept underlying solutions as described herein, which facilitate generating an IC supply voltage with a high conversion efficiency.

FIG. 6 is a more detailed circuit diagram of possible implementations corresponding to the blocks 18, 19 and 20 in order to provide a control loop for voltage regulation of the supply voltage V_{CC}.

The circuit in FIG. 6 is built around two nodes, labeled A and B.

The node A is coupled to a ground GND via a resistor R₂ and a first current generator I₁ is configured (in a manner known to those of skill in the art) to draw a current of intensity I₁ =(V_{ref}−V_{CC})/R₁ from the node A.

It is otherwise recalled that, for the sake of simplicity and ease of explanation, a same designation can be used in this description to designate:
a node or line as well as a signal occurring at that node or line;
a component (such as a capacitor, resistor or inductor or coil) as well as electrical parameters (capacitance, resistance, inductance) thereof.

The node A is coupled to a supply node or rail at a voltage V_{DD} via a second current generator I₂ configured (in a manner known to those of skill in the art) to draw from the node V_{DD} a current of intensity I₂.

A first electronic switch sw1 (implemented in any manner known to those of skill in the art) is interposed between the nodes A and B and configured to be controlled via a logically negated version of the signal START CHARGE and thus to be:
non-conductive in response to the signal START CHARGE being “high” (logical “1”), and
conductive in response to the signal START CHARGE being “low” (logical “0”).

The node B Is coupled to ground via one or more storage capacitors having a capacitance value C_{SC}.

The node B is likewise coupled to the supply node or rail at a voltage V_{DD} via a third current generator I₃ configured (in a manner known to those of skill in the art) to draw from the node V_{DD} a current of intensity I₃.

Coupling of the node B to the supply node or rail at a voltage V_{DD} is via a second electronic switch sw2 (implemented in any manner known to those of skill in the art) configured to be controlled via the signal START CHARGE and thus to be:
conductive in response to the signal START CHARGE being “high” (logical “1”), and
non-conductive in response to the signal START CHARGE being “low” (logical “0”).

Reference 182 denotes a comparator having:
a first (non-inverting, for instance) input coupled to the node B,
a second (inverting, for instance) input set to a threshold level Vₜₕ=I₂*R₂, and
an output providing the signal STOP_CHARGE.

Reference 184 denotes a logic gate (AND, for instance) having:
a first input coupled to the output of the comparator 182 to receive therefrom a (logically inverted) replica of the signal STOP_CHARGE, that is, (STOP_CHARGE)neg;
a second input configured to receive the signal START_CHARGE (generated in manner known per se: see FIG. 5), and
an output providing the signal EN_CHARGE.

The signal EN_CHARGE (charge enable) can thus be assumed to be:
“high” (logic “1”), thus enabling charge of the capacitor C_{VCC}, in response to both the signal START_CHARGE and the signal (STOP_CHARGE)neg being likewise “high” (logic “1”), that is with START_CHARGE being “high” (logic “1”) and STOP_CHARGE being “low” (logic “0”);
“low” (logic “0”), thus disabling charge of the capacitor C_{VCC}, in response to either the signal START_CHARGE being “low” (logic “0”) or the signal (STOP_CHARGE)neg being “high” (logic “1”), that is with START_CHARGE being “low” (logic “0”) or STOP_CHARGE being “high” (logic “1”).

Operation of the circuit in FIG. 6 can be described from a starting phase (a) where the signal START_CHARGE is “low” (logic 0) and the switch sw1 is closed (conductive) with the switch sw2 open (non-conductive).

In this phase the voltages at nodes A and B are the same and equal to:

[I₂−(V_{ref}−V_{CC})/R₁]*R₂

and follow the instantaneous value of V_{CC}.

The choice of the values of the fixed parameters I₂, R₁ and R₂ will be discussed in the following.

The current I₁ in the figure is generated by an analog block (a voltage-current converter via a resistor having a resistance value R₁) that receives the voltages V_{ref} and V_{CC} as input.

Phase (b) is entered on the positive edge of the signal START_CHARGE: the switch sw1 opens and the node B is disconnected from the node A, sampling the voltage value currently present on the capacitor C_{SC}.

The voltage difference between the reference threshold Vth (of the comparator 182) and node B is equal to the error voltage:

[(V_{ref}−V_{CC})*R₂]/R₁.

At the same time, the switch sw2 is closed and a voltage ramp with slope I₃/C_{SC} will be added to the voltage value present at node B.

During this phase, since the voltage SWNV is higher than the voltage V_{CC}, the self-supply circuit will be able to charge the node V_{CC} with a slope given by I_{CHARGE}/C_{VCC}.

In response to the voltage on node B reaching the threshold voltage Vₜₕ (making an overall voltage excursion equal to the error voltage reported above), phase (c) is entered: the signal STOP_CHARGE goes to “high” (logic level 1) and interrupts the charging of V_{CC}.

Structure of the circuit illustrated in FIG. 6 can thus be summarized as follows:
first current generator circuitry (the current generators I₁, I₂) is configured to be coupled via the switch sw1 to a storage capacitance C_{SC} in response to the voltage SWNV at the first node K being lower than the voltage at the second node V_{CC} and to store on the storage capacitance C_{SC} a first voltage (at node A) indicative an actual value of the voltage at the second node V_{CC};
further current generator circuitry I₃ is configured to be coupled via the switch sw2 to the storage capacitance C_{SC} in response to the voltage SWNV at the first node K being higher than the voltage at the second node V_{CC} and to add to the first voltage stored on the storage capacitance C_{SC} a further voltage ramp; and
a comparator 182 is configured to compare with a threshold Vₜₕ a sum (formed at node B) of the first voltage stored on the storage capacitance C_{SC} and the further voltage ramp and terminate (the signal STOP_CHARGE goes “high”) the charging time Δtch in response to that sum reaching the threshold Vₜₕ.

As illustrated, the first current generator circuitry comprises:
a first current source configured to produce a first current I₁ indicative of the difference between the target value V_{ref} and the actual value of the voltage at the second node V_{CC};
a second current source configured to produce a second current I₂ coupled to the first current source at a current combination node A wherein the first current I₁ is subtracted from the second current I₂.

FIG. 7 is a timing diagram showing-again against a common abscissa time scale t-possible time behaviors (waveforms) of signals that may occur in a circuit as illustrated in FIG. 6.

More specifically, in FIG. 7 possible time behaviors during phases (a), (b), and (c) are shown of the following signals (from top to bottom):
the voltage at node A and the voltage at node B (dashed line), both plotted against the voltage threshold Vth;
the signal START_CHARGE; and
the signal STOP_CHARGE.

The equations underlying operation of the circuit in FIG. 6 demonstrate that the duration of the charging window Δtch is directly proportional to the error voltage (V_{ref}−V_{CC}) sampled on the positive transition of the signal START_CHARGE in accordance with the first equation captioned in the foregoing:

More specifically:

if (V_{ref}−V_{CC})<I₂*R₁→Δtch=(V_{ref}−V_{CC})*R₂/R₁*C_{SC}/I₃,

and

if (V_{ref}−V_{CC})≥I₂*R₁→Δtch=I₂*R₂*C_{SC}/I₃

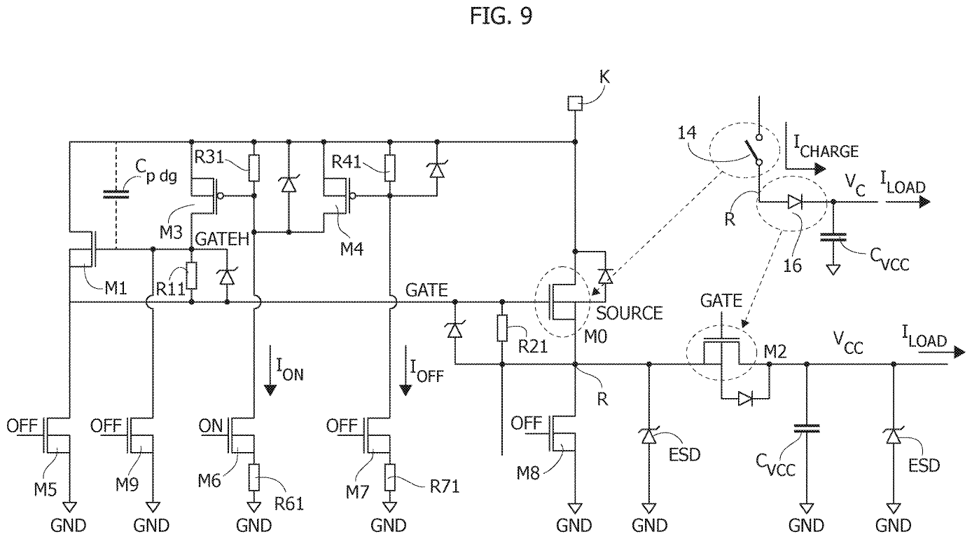

This latter condition is obtained when the error voltage (V_{ref}−V_{CC}) generates a current I₁ equal to I₂ for so that the node A remains at 0V: in this case Δtch assumes its maximum value as illustrated in FIG. 8, where the value Δtch (ordinate scale) is portrayed versus the difference V_{ref}−V_{CC} (abscissa scale).

The values for I₂, R₁, R₂, C_{SC} (capacitance C), and I₃ can be selected in such a way to take into account the charge balance equation at the end of the charging window of duration Δtch discussed in the foregoing and the system specifications in terms of ripple on V_{CC} and dissipated power.

An advantage of solutions as proposed herein, when compared with a conventional hysteresis control, is that in steady-state conditions the value of Δtch will be constant (at the minimum value for an operating condition in place) and support a desired value for the voltage V_{CC} with a reduced dissipation of the power drawn from the switching node and a minimum ripple on V_{CC}.

As discussed previously, in solutions as proposed herein a switch (such as the switch 14 in FIG. 3) arranged in series with the charging path of the capacitor C_{VCC} should desirably facilitate a shortest turn-on time compatible with having a lowest series resistance R_{ONSW} of the switch when conductive. In general terms, reducing the resistance R_{ONSW} involves increasing the dimensions of the component acting as the switch, which in turn militates against having a reduced turn-on time (due to increased parasitic capacitances).

FIG. 9 is a circuit diagram of a “fast” turn-on switch usable in a circuit like the example of FIG. 3 (the exemplary implementation illustrated refers to a low-side configuration in so far as this simplifies the timing signal description) in order to facilitate satisfactory performance even if the two characteristics above are not easy to achieve jointly.

Specifically, the circuit diagram of FIG. 9 is illustrative of circuitry suited to implement the basic arrangement of the switch 14 of FIG. 3.

A portion of that figure (showing also the diode 16 and the capacitor C_{VCC} and indicating the currents I_{CHARGE} and I_{LOAD}) is reproduced at the upper right-hand corner of FIG. 9 for immediate reference.

The circuit diagram of FIG. 9 exemplifies a switch 14 suited to be implemented in a SMPS converter.

That architecture, suited to draw current (power) from a switching node during the positive edge in a controlled and fast manner, can be implemented with a low series resistance, with small area occupation and can be activated quickly.

The switch 14 shown in the FIG. 9 is built around a transistor M0 (by way of example, a high-voltage n-channel MOSFET transistor) having a current flow path (source-drain in the case of a field-effect transistor such as a MOSFET transistor).

The transistor M0 is configured to be arranged in a current flow line for the current I_{CHARGE} between the (low-impedance) switching node K (in a SMPS converter, for instance: for simplicity, this not visible in its entirety in FIG. 9, but FIG. 2 and FIG. 3 can be referred to by way of background) and a node at a self-generated supply voltage V_{CC}.

In FIG. 9, a transistor M2 (by way of example, a high-voltage n-channel MOSFET transistor, used to implement the diode 16, to achieve a better efficiency) is illustrated arranged with the current flow path therethrough (source-drain in the case of a field-effect transistor such as a MOSFET transistor) intermediate the transistor M0 and the node at the supply voltage V_{CC}.

It is once more recalled that, for the sake of simplicity and ease of explanation, a same designation can be used in this description to designate:
a node or line as well as a signal occurring at that node or line;
a component (such as a capacitor, resistor or inductor or coil) as well as electrical parameters (capacitance, resistance, inductance) thereof.

The sizing of the transistor M0 depends on the topology of the converter and on an efficiency target set for conversion.

In a circuit as illustrated in FIG. 9, a fast turn-on of the switch 14 to render it conductive (that is, a rapid turn-on of the transistor M0) is facilitated by a rising edge of the switching node K as a function of the time derivative (slope) dv/dt of the voltage at that node.

For instance:
for high values of dv/dt at the switching node, the main switch M0 is turned on via a transistor M1 (n-channel FET, for instance) that is rendered conductive via its parasitic drain-gate capacitance C_{p_dg}; and
for values of dv/dt that are not high enough, an additional transistor M3 (p-channel FET, for instance) is used that is configured to be driven in order to turn on the main switch M0.

As illustrated in FIG. 9:
the transistor M1 is arranged with the current flow path therethrough (source-drain in the case of a field-effect transistor such as a MOSFET transistor) coupled between the node K and the control electrode (labelled GATE in the present case of a field-effect transistor such as a MOSFET transistor) of the “main” transistor M0; and
the transistor M3 is arranged with the current flow path therethrough (source-drain in the case of a field-effect transistor such as a MOSFET transistor) coupled between the node K and a node GATEH that is in turn coupled via a gate clamp including a resistor R11 to the control electrode GATE of the “main” transistor M0.

The circuitry illustrated in FIG. 9 can advantageously include various additional components.

For instance, the transistor M2 (already discussed) is coupled to the transistor M0 (at the SOURCE, thereof, for instance) in a back-to-back configuration at the node R. This facilitates decoupling the node V_{CC} (self-generated power supply) from the switching node K when the latter is at a voltage lower than the voltage at the node V_{CC} which counters undesired discharging of the storage capacity C_{VCC} of the generated power supply, thus providing a rectifying effect on the current I_{LOAD}.

Current flow between the switching node K and the node V_{CC} can be made less dissipative by driving the transistor M2 (via a signal applied to the gate thereof in a manner known per se to those of skill in the art) with the same signal that drives the gate of the transistor M0.

In those solutions where the dissipated power is not subject to particular specifications, the transistor M2 can be simply replaced by a diode.

That is, in solutions as proposed herein, a rectifier is arranged intermediate the switch 14 and the second node V_{CC}.

The rectifier can comprise a diode (the diode 16 in FIG. 3) or a transistor (the transistor M2 in FIG. 9) configured to be rendered non-conductive and decouple the first node K from the second node V_{CC} in response to the voltage SWNV at the switching node K being lower than the voltage at the node V_{CC}.

The circuitry illustrated in FIG. 9 also includes other transistors such as the transistors M4, M5, M6, M7, M8 and M9.

As in the case of the transistors M0, M1, M2, and M3 already discussed in the foregoing, the description related to FIG. 9 (and the whole of the present description) is illustrative of a field-effect transistor (FET) implementation. A bipolar junction transistor (BJT) implementation is likewise possible, in which the control terminal will be the base of these transistors (in the place of the gate) and the current path therethrough will be represented by the emitter-collector current flow path (in the place of the source-drain current flow path).

Likewise, the description related to FIG. 9 (and the whole of the present description) is illustrative of an implementation of the circuit 10 where the voltages at the node K and V_{CC} are assumed to be positive, with the polarities of the transistors (p-channel/n-channel and p-n-p/n-p-n) selected correspondingly. Those of skill in the art can easily devise corresponding adaptations in case of negative voltages.

As illustrated in FIG. 9, the transistors M4, M5, M6, M7, M8 and M9 are arranged:
the transistor M4, with the current flow path therethrough cascaded with the current flow path through the transistor M6 in a current flow line between the node K and ground GND with a resistor R61 between the transistor M6 and ground;
the transistor M5, with the current flow path therethrough between the gate of the transistor M0 and ground GND;
the transistor M7, with the current flow path therethrough between a gate clamp including a resistor R41 coupled to the node K and a resistor R71 referred to ground GND;
the transistor M8, with the current flow path therethrough between a node R (intermediate the transistor M0 and the transistor M2) and ground GND; and
the transistor M9, with the current flow path therethrough between the gate of the transistor M1 and ground GND.

The gates of the various transistors in the circuit are protected by gate clamps GC (voltage clamps) and driven through resistors such as the resistors R11, R21, R31, R41 and associated Zener diodes (for simplicity, these are illustrated but not expressly referenced like the body diodes of the transistors M0 and M2) to counter undesired breakdowns at high dv/dt due to turn-on/off events.

Additional (static) clamps, labelled ESD, may be provided between the node D and ground GND and between the node V_{CC} to counter undesired ElectroStatic Discharge (ESD) phenomena.

An advantage of architecture illustrated in FIG. 9 lies in that the transistor M0 (acting as a high-voltage switch) can also perform an ESD protection function for the switching node K in combination with the ESD clamps (these may have a lower voltage class than the switching node and therefore of reduced area). In that way, a dedicated/additional high-voltage (and consequently large-area) ESD protection for the switching node K is not required.

That is, as illustrated in FIG. 9, the switch comprises a high-voltage transistor M0 and the rectifier has associated thereto at least one low-voltage electronic static discharge clamp, ESD.

The transistors M5, M7, M8, and M9 can be adequately driven (in a manner known per se to those of skill in the art) and switched on (rendered conductive) to turn off (render non-conductive) the switch M0:
directly, by acting on the associated gate and source networks, and
indirectly, by turning off (rendering non-conductive) the transistor M1 (by acting on the node GATEH) and the transistor M3 (by turning on, that is making conductive, the transistor M4).

With these transistors maintained off (non-conductive) and therefore with the associated gate and source networks (and the node GATEH) floating, the circuit is enabled to turn on (render conductive) the switch (transistor M0) in response to a (positive) edge on the switching node.

The (n-channel) transistor M6 can be used to turn on the switch M0 through the auxiliary (p-channel) transistor M3 as described previously.

FIG. 10 is a timing diagram showing-against a common abscissa time scale t-possible time behaviors (waveforms) of signals that may occur in a circuit as illustrated in FIG. 9.

More specifically, FIG. 10 shows possible time behaviors of the following signals (from top to bottom):
the voltage, SWNV at the switching node (the same representation of FIG. 4 is adopted for simplicity);
the ON and OFF voltages applied to the transistors M5, M6, M9, M7, and M8 in FIG. 9 (ON=1→conductive; OFF=1→non-conductive;
the gate-source voltage V_{GS}(M1) of the transistor M1;
the gate-source voltage V_{GS}(M0) of the transistor M0; and
the current I_{CHARGE} that is zero when the switch is DISABLED and gradually ramps up to a peak value in response to the switch being ENABLED.

In a circuit as illustrated in FIG. 9, switching on (rendering conductive) of the switch/transistor M0 takes place in a controlled manner at the rising edge of the switching node K thus facilitating current flow of the current I_{CHARGE} to charge the capacitor C_{VCC} capacitance.

The illustrated ON and OFF driving signals are mutually complementary: they negate each other.

In response to the OFF signal being kept “high” (logic 1), the switch M0 is disabled: the transistor M0 cannot be switched on (rendered conductive) in response to dv/dt on the positive edge of the switching node K. Nor can this occur via the switch M3.

In response to the OFF signal being brought to “low” (logic 0), the switch M0 is enabled to switch on for high dv/dt at the switching node K.

The time instant at which the OFF signal transitions to “low” may be when the voltage at the switching node K crosses a threshold (if the transistor M2 is replaced by a diode) or when the voltage at the switching node K exceeds the voltage at the node V_{CC} (if the transistor M2 is present and switched on).

The node GATEH, plus the gate and source terminals of the transistor M0 are left floating and the voltage at the node GATEH will increase due to the capacitive injection due to the capacitance C_{p gd} of the MOSFET transistor M1 (only) in the presence of a high dv/dt at the switching node K.

When the node GATEH reaches the threshold voltage of the MOFET transistor M1, the MOSFET M1 turns on (becomes conductive) and starts to charge the network associated with the gate of the transistor M0 by causing the switch M0 to become conductive with a (drain) current therethrough corresponding to the current I_{CHARGE} as per the following relationship:

I_{CHARGE}=I_{D(M0)}=(SWNV−V_{DROP(M0,M2)}−V_{CC})/R_{DSON(M0)}

where:
SWNV is the instantaneous voltage at the switching node K
V_{DROP(M0,M2)} is the voltage drop across the series connection of the current flow paths through the transistors M0 and M2; and
R_{DSON(M0)} is the (drain-to-source) resistance of the transistors M0 acting a switch when conductive.

The size of the transistor M1 defines a corresponding saturation current IDS_SAT(1).

The time taken to turn on (render conductive) the transistor M0 depends on the current IDS_SAT(1) and on the gate-source capacitance C_{GS(M0)} of the transistor M0. The capacitance C_{GS(M0)} is related to width of the transistor M0, which is set to obtain a desired target value for the resistance R_{DSON(M0)}.

When going to a high logic level, the ON signal turns on (renders conductive) the p-channel transistor M3 with a moderate current in such a way as to raise the node GATEH (with slower times) even when the rising edge at the switching node K has a low value for dv/dt (therefore a higher rise time) and as such would not be sufficient to turn on (render conductive) the MOS transistor M1.

To summarize, a general concept underlying solutions as illustrated in FIG. 9 is that the switch referred to as 14 in FIG. 3 is implemented via a charge transistor M0 having a control terminal GATE and a current flow path therethrough configured, in response to the current flow path being conductive, to provide a current flow line for the charge current I_{CHARGE} to flow (via the transistor M2) from the first node K towards the capacitor C_{VCC} coupled to the second node V_{CC}.

In the circuit illustrated in FIG. 9:
a first switch control transistor M1 has a current flow path therethrough coupled between the first node K and the control terminal GATE of the charge transistor M0,
the first switch control transistor M1 has a parasitic capacitance C_{p_dg} between the first node K and a respective control terminal; and
a second switch control transistor M3 has a respective current flow path therethrough coupled (at the node GATEH) between the first node K and the control terminal GATEH controlling the gate of the first control switch M1, so that the respective current flow path of second switch control transistor M3 is configured for selective activation via the transistor M6, and
the current flow path through the charge transistor M0 is configured to be rendered conductive in the presence of a voltage transitory at the first node K by either one of:
i) the parasitic capacitance C_{p_dg} of the first switch control transistor M1, or
ii) via activation (thanks to the transistor M6) of the respective current flow path through the second switch control transistor M3.

In the circuit illustrated in FIG. 9, at least one switch-off transistor (see the transistors M5, M7, M8, M9) are coupled to the charge transistor M0 and configured to be activated (switched “ON”, and thus made conductive) to render the current flow path through the charge transistor M0 non-conductive.

As illustrated in FIG. 9, the at least one switch-off transistor is coupled to:
the control terminal GATE of the charge transistor M0 (in the case of the transistors M5, M7, and M9) or
the current flow path through the charge transistor M0 (in the case of the transistor M8).

As illustrated in FIG. 9, the at least one switch-off transistor is coupled to the charge transistor M0 via:
the first switch control transistor M1 (in the case of the transistor M5); or
the second switch control transistor M3, in co-operation with the transistor M4, in the case of the transistor M7.

A circuit as illustrated in FIG. 9 is thus able to operate on different edges (high or low dv/dt) at the switching node K.

Current flow of the current I_{CHARGE} end when the OFF signal, driven by a control loop for the regulation of the voltage V_{CC}, returns to the high logic value.

Sizing of the transistor M0 may take into account various factors such as:
the current I_{LOAD} expected to applied to the load connected to the node V_{CC};
an equivalent charging voltage adequate to avoid excessive power dissipation (and this to avoid negatively impacting the conversion efficiency of the converter): having a low value for the resistance R_{DSON} facilitates drawing a high current in a short time interval (desirably a fraction of the rising edge at the switching node K);
the highest current that can be absorbed by the switching node K without appreciably deforming the waveform thereof.

Solutions as proposes in FIG. 9 facilitate implementing a high-voltage switch with a low series resistance, a fast turn-on times and a small occupation area suited for use in a switching node of in a converter for a generic SMPS (switched-mode power supply, also referred to as switching-mode power supply, switch-mode power supply, switched power supply, or simply switcher, namely an electronic power supply that incorporates a switching regulator to convert electrical power) for use, for instance, in supplying an associated integrated circuit or IC.

Without prejudice to the underlying principles, the details and embodiments may vary, even significantly, with respect to what has been described by way of example only without departing from the extent of protection.

The extent of protection is determined by the annexed claims.

What is claimed is:

1. A circuit having a first node configured to receive a switched voltage and a second node configured to produce a load current, wherein the circuit comprises:
a capacitor coupled to the second node and configured to provide the load current in response to electrical charge being drawn therefrom;
a switch coupled between the first node and the second node, the switch configured, in response to being conductive, to provide a current flow line for a charge current between the first node and the capacitor coupled to the second node, wherein the electrical charge is charged onto the capacitor via the charge current; and
control circuitry of the switch, wherein the control circuitry is configured to detect the voltage at the first node and the voltage at the second node and to render the switch conductive during a charging time of the capacitor during a rising edge of the first node in response to the voltage at the first node being higher than the voltage at the second node.

2. The circuit of claim 1, wherein the control circuitry of the switch is configured to:
receive a target value for the voltage at the second node; and
control the charging time as a function of a difference between the target value and an actual value of the voltage at the second node.

3. The circuit of claim 1, wherein the control circuitry comprises:
a storage capacitance;
first current generator circuitry configured to be coupled to the storage capacitance in response to the voltage at the first node being lower than the voltage at the second node and to store on the storage capacitance a first voltage indicative an actual value of the voltage at the second node;
further current generator circuitry configured to be coupled to the storage capacitance in response to the voltage at the first node being higher than the voltage at the second node and to add to the first voltage stored on the storage capacitance a further voltage ramp; and
a comparator configured to compare with a threshold a sum of the first voltage stored on the storage capacitance and the further voltage ramp and terminate the charging time in response to the sum reaching the threshold.

4. The circuit of claim 3,
wherein the control circuitry of the switch is configured to:
receive a target value for the voltage at the second node; and
control the charging time as a function of a difference between the target value and the actual value of the voltage at the second node; and
wherein the first current generator circuitry comprises:
a first current source configured to produce a first current indicative of the difference between the target value and the actual value of the voltage at the second node; and
a second current source configured to produce a second current, the second current source coupled to the first current source at a current combination node wherein the first current is subtracted from the second current.

5. The circuit of claim 1, further comprising a rectifier arranged intermediate the switch and the second node.

6. The circuit of claim 5, wherein the rectifier comprises a diode.

7. The circuit of claim 5, wherein the rectifier comprises a transistor configured to be rendered non-conductive and decouple the first node from the second node in response to the voltage at the first node being lower than the voltage at the second node.

8. The circuit of claim 5, wherein the switch comprises a high-voltage transistor and the rectifier has associated thereto at least one low-voltage electronic static discharge clamp.

9. The circuit of claim 1, wherein the switch comprises a charge transistor having a control terminal and a current flow path therethrough configured, in response to the current flow path being conductive, to provide the current flow line for the charge current from the first node towards the capacitor coupled to the second node.

10. The circuit of claim 9, further comprising:
a first switch control transistor having a first current flow path therethrough coupled between the first node and the control terminal of the charge transistor, wherein the first switch control transistor has a parasitic capacitance between the first node and a respective control terminal; and
a second switch control transistor having a second current flow path therethrough coupled between the first node and the control terminal of the charge transistor, wherein the second current flow path of second switch control transistor is configured for selective activation;
wherein the current flow path through the charge transistor is configured to be rendered conductive in a presence of a voltage transitory at the first node by either the parasitic capacitance of the first switch control transistor or via activation of the second current flow path through the second switch control transistor.

11. The circuit of claim 9, further comprising at least one switch-off transistor coupled to the charge transistor and configured to be activated to render the current flow path through the charge transistor non-conductive.

12. The circuit of claim 11, wherein the at least one switch-off transistor is coupled to one of the control terminal of or the current flow path through the charge transistor.

13. The circuit of claim 10, further comprising at least one switch-off transistor coupled to the charge transistor and configured to be activated to render the current flow path through the charge transistor non-conductive;
wherein the at least one switch-off transistor is coupled to one of the control terminal of or the current flow path through the charge transistor; and
wherein the at least one switch-off transistor is coupled to the charge transistor via the first switch control transistor or the second switch control transistor.

14. A switched-mode power supply converter comprising:
a circuit comprising:
a first node configured to receive a switched voltage;
a second node configured to produce a load current;
a capacitor coupled to the second node and configured to provide the load current in response to electrical charge being drawn therefrom;
a switch coupled between the first node and the second node, the switch configured, in response to being conductive, to provide a current flow line for a charge current between the first node and the capacitor coupled to the second node, wherein the electrical charge is charged onto the capacitor via the charge current; and
control circuitry of the switch, wherein the control circuitry is configured to detect the voltage at the first node and the voltage at the second node and to render the switch conductive during a charging time of the capacitor during a rising edge of the first node in response to the voltage at the first node being higher than the voltage at the second node; and
a source of the switched voltage, wherein the source is coupled to the first node.

15. The switched-mode power supply converter of claim 14, wherein the switched-mode power supply converter comprises one of a boost converter, a forward converter, a flyback converter, a push-pull converter, or an LLC resonant converter.

16. The switched-mode power supply converter of claim 14, wherein an electrical load comprises the switched-mode power supply converter, and wherein the electrical load is coupled to the second node and configured to draw therefrom the load current.

17. A method of producing from a switched voltage applied to a first node a load current at a second node, the method comprising:
providing, by a capacitor coupled to the second node, the load current in response to an electrical charge being drawn from the capacitor;
providing, by a switch coupled between the first node and the second node, in response to the switch being conductive, a current flow line for a charge current between the first node and the capacitor coupled to the second node, the electrical charge being charged onto the capacitor via the charge current;
detecting the voltage at the first node and the voltage at the second node; and
rendering the switch conductive during a charging time of the capacitor during a rising edge of the first node in response to the voltage at the first node being higher than the voltage at the second node.

18. The method of claim 17, further comprising:
receiving a target value for the voltage at the second node; and
controlling the charging time as a function of a difference between the target value and an actual value of the voltage at the second node.

19. The method of claim 18, further comprising:
coupling, a first current generator circuitry to a storage capacitance, in response to the voltage at the first node being lower than the voltage at the second node;
storing, by the first current generator circuitry on the storage capacitance, a first voltage indicative of the actual value of the voltage at the second node;
coupling, a further current generator circuitry to the storage capacitance, in response to the voltage at the first node being higher than the voltage at the second node;
adding, by the further current generator circuitry to the first voltage stored on the storage capacitance, a further voltage ramp;
comparing, by a comparator, with a threshold a sum of the first voltage stored on the storage capacitance and the further voltage ramp; and
terminating, by the comparator, the charging time in response to the sum reaching the threshold.

20. The method of claim 19, further comprising:
producing, by a first current source of the first current generator circuitry, a first current indicative of the difference between the target value and the actual value of the voltage at the second node;
producing, by a second current source of the first current generator circuitry, a second current; and
subtracting, at a current combination node of the second current source and the first current source, the first current from the second current.
